(19) United States
(12) Patent Application Publication
(10) Pub. No.: US 2024/0403514 A1
(43) Pub. Date: Dec. 5, 2024

(54) METHOD, SYSTEM AND DEVICE FOR ALLOCATING TOTAL EMISSION REDUCTION OF WATER ENVIRONMENTAL POLLUTION LOAD

(71) Applicant: Dalian University of Technology, Dalian City (CN)

(72) Inventors: Zhuohang XIN, Dalian City (CN); Ming CONG, Dalian City (CN); Zhihong LIU, Dalian City (CN); Chi ZHANG, Dalian City (CN)

(21) Appl. No.: 18/487,559

(22) Filed: Oct. 16, 2023

(30) Foreign Application Priority Data
Jun. 2, 2023 (CN) 2023106472664

(51) Int. Cl. G06F 30/20

(52) U.S. Cl. CPC G06F 30/20

(57) ABSTRACT

A method, system and device for allocating total emission reduction of a water environmental pollution load are provided. The method includes: dividing a watershed based on terrain elevation information in watershed-related data to generate a plurality of watershed control units; with a watershed control unit as a basic unit, estimating a pollution load output in each watershed control unit by using an output coefficient method; acquiring GDP of each watershed control unit, and combined with the pollution load output, calculating relative environmental efficiency of each watershed control unit by using a data envelopment method; quantifying a contribution rate of a pollution load produced by each watershed control unit to a pollution load of a section of river entering the sea one by one based on a constructed watershed water environmental model; and formulating a pollutant emission reduction scheme according to the relative environmental efficiency and the contribution rate.

### CROSS-REFERENCE TO RELATED APPLICATION

This patent application claims the benefit and priority of Chinese Patent Application No. 2023106472664 filed with the China National Intellectual Property Administration on Jun. 2, 2023, the disclosure of which is incorporated by reference herein in its entirety as part of the present application.

### TECHNICAL FIELD

The present disclosure relates to the field of emission reduction of water environment pollution, and in particular to a method, system and device for allocating total emission reduction of a water environmental pollution load.

### BACKGROUND

76% to 90% of offshore pollutants originate from terrestrial areas, and terrestrial pollution, once being produced, will migrate and transfer with the hydrological processes in the watershed and finally enter the ocean via rivers. There is an urgent need to strictly control the water quality of river entering the sea by reducing terrestrial pollution loads, particularly for watersheds with excessive emissions, thereby ensuring the water ecological environment health of the watershed-offshore continuum

At present, China mostly adopts target gross control for pollutant emission reduction, that is, the actual pollutant flux entering the sea at the section of river entering the sea is calculated, and a difference between the pollutant flux entering the sea and the standard flux entering the sea is made, so as to obtain the pollution load that should be reduced in the watershed of the section of river entering the sea. The flux entering the sea is produced by natural processes and human activities in the whole space of the watershed. Thus, when the total amount of emission reduction is obtained, how to effectively implement the emission reduction task is the key to determine whether the flux of the section of river entering the sea can reach the standard. At present, the emission reduction task is mostly allocated to each control unit according to the experience of management decision makers and expert suggestions, or based on the contribution proportion of pollution load of different control units. Although the environmental impacts of different units are considered in existing methods, the negative impacts on industry and agriculture after emission reduction are ignored. For example, a certain region has a large amount of pollution load, but its contribution to economic and social development is relatively greater. The emission reduction for this region according to the contribution degree of pollution load will directly reduce the social and economic output of the region and restrict regional development. Therefore, the application feasibility of the current total pollution load emission reduction scheme is low, which restricts the implementation of land-sea water environment protection strategy.

### SUMMARY

An objective of some embodiments of the present disclosure is to provide a method, system and device for allocating total emission reduction of a water environmental pollution load, so as to solve the problem that the feasibility of the current total pollution load emission reduction scheme is low.

In order to achieve the above objective, the present disclosure provides the following solution.

A method for allocating total emission reduction of a water environmental pollution load includes:
dividing a watershed based on terrain elevation information in watershed-related data to generate multiple watershed control units, where the watershed-related data includes meteorology, topographic elevation information, land use information, river water quality, runoff, industrial pollution emission, sewage treatment plant emission, population, livestock and poultry breeding, agricultural planting and county GDP of the watershed;
with a watershed control unit as a basic unit, estimating a pollution load output in each watershed control unit by using an output coefficient method, where the pollution load output includes pollution loads produced by an industrial point source, a sewage treatment plant, agricultural planting, livestock and poultry breeding, and rural life;
acquiring GDP (Gross Domestic Product) of each watershed control unit, and combined with the pollution load output, calculating relative environmental efficiency of each watershed control unit by using a data envelopment method, where the relative environmental efficiency is an economic benefit brought by the pollution output of each watershed control unit;
quantifying a contribution rate of a pollution load produced by each watershed control unit to a pollution load of a section of river entering the sea one by one based on a constructed watershed water environmental model, where the contribution rate is influence of the pollution load produced by each watershed control unit on a water environment of the section of river entering the sea; and
formulating a pollutant emission reduction scheme considering both an economic benefit and an environmental impact according to the relative environmental efficiency and the contribution rate, where the pollutant emission reduction scheme is used for allocating total emission reduction of the water environmental pollution load for each watershed control unit.

A system for allocating total emission reduction of a water environmental pollution load includes:
a division module, configured to divide a watershed based on terrain elevation information in watershed-related data to generate multiple watershed control units, where the watershed-related data includes meteorology, topographic elevation information, land use information, river water quality, runoff, industrial pollution emission, sewage treatment plant emission, population, livestock and poultry breeding, agricultural planting and county GDP of the watershed;
an estimation module, configured to estimate a pollution load output in each watershed control unit with a watershed control unit as a basic unit and by using an output coefficient method, where the pollution load output includes pollution loads produced by an industrial point source, a sewage treatment plant, agricultural planting, livestock and poultry breeding, and rural life;
a relative environmental efficiency calculation module, configured to acquire GDP (Gross Domestic Product) of each watershed control unit, and combined with the pollution load output, to calculate relative environmental efficiency of each watershed control unit by using a data envelopment method, where the relative environmental efficiency is an economic benefit brought by the pollution output of each watershed control unit;
a contribution rate calculation module, configured to quantify a contribution rate of a pollution load produced by each watershed control unit to a pollution load of a section of river entering the sea one by one based on a constructed watershed water environmental model, where the contribution rate is influence of the pollution load produced by each watershed control unit on a water environment of the section of river entering the sea; and
a pollutant emission reduction scheme formulating module, configured to formulate a pollutant emission reduction scheme considering both an economic benefit and an environmental impact according to the relative environmental efficiency and the contribution rate, where the pollutant emission reduction scheme is used for allocating total emission reduction of the water environmental pollution load for each watershed control unit.

An electronic device includes a memory and a processor. The memory is used for storing a computer program, and the processor is used to run the computer program to enable the electronic device to execute above method for allocating total emission reduction of the water environmental pollution load.

A computer-readable storage medium has a computer program stored thereon. The computer program, when executed by a processor, implements the method for allocating total emission reduction of the water environmental pollution load.

According to specific embodiment provided by the present disclosure, the following technical effects are provided. A method, system and device for allocating total emission reduction of a water environmental pollution load are provided. A watershed is divided into multiple watershed control units based on watershed-related data, the watershed control units are used as basic units to estimate a pollution load output in each watershed control unit, and the economic benefit brought by the pollution output is calculated. Moreover, combined with a contribution rate of a pollution load produced by each watershed control unit to a pollution load of the section of river entering the sea, a pollutant emission reduction scheme considering both an economic benefit and an environmental impact is formulated, which is used for allocating the total emission reduction of water environmental load for each watershed control unit. Therefore, the economic benefit is guaranteed, the water environment of the watershed is improved, and the feasibility of the pollutant emission reduction scheme is improved.

### BRIEF DESCRIPTION OF THE DRAWINGS

To describe the technical solutions in the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a flow chart of a method for allocating total emission reduction of a water environmental pollution load in accordance with Embodiment I of the present disclosure;

FIG. 2 is a flow chart of a method for allocating total emission reduction of a water environmental pollution load in accordance with Embodiment II of the present disclosure;

FIG. 3 is a location map of a main stream, a watershed, a weather station, a hydrometric station, a water quality monitoring station and a reservoir of Liaohe River in accordance with Embodiment II of the present disclosure;

FIG. 4 is a division diagram of control units of a main stream of Liaohe River in accordance with Embodiment II of the present disclosure;

FIG. 5 is a distribution diagram of an output load of ammonia nitrogen pollution of each watershed control unit in accordance with Embodiment II of the present disclosure;

FIG. 6 is a distribution diagram of economic efficiency of a control unit calculated by DEA (Data Envelopment Analysis) in accordance with Embodiment II of the present disclosure;

FIG. 7 is an ammonia nitrogen calibration result diagram of a water environmental model in accordance with Embodiment II of the present disclosure;

FIG. 8 is a distribution diagram of an environment impact (contribution rate) of each watershed control unit in accordance with Embodiment II of the present disclosure;

FIG. 9 is a schematic diagram of an emission reduction scheme for a control unit considering both economic benefit and environmental impact in accordance with Embodiment II of the present disclosure;

FIG. 10 is comparison diagram of an emission reduction scheme only considering environmental impact in accordance with Embodiment II of the present disclosure.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely some rather than all of the embodiments of the present disclosure. All other embodiments obtained by those of ordinary skill in the art based on the embodiments of the present disclosure without creative efforts shall fall within the protection scope of the present disclosure.

An objective of some embodiments of the present disclosure is to provide a method, system and device for allocating total emission reduction of a water environmental pollution load, so as to improve the feasibility of a pollutant emission reduction scheme.

To make the above objective, features and advantages of the present disclosure clearer and more comprehensible, the following further describes the present disclosure in detail with reference to the accompanying drawings and the specific embodiments.

As the essence of water environmental problem is born from social and economic development, and will certainly be solved in the development, the water environment emission reduction scheme without considering social and economic benefits cannot meet the requirements of sustainable development. Therefore, when the emission reduction scheme is formulated, an efficient and equitable pollution reduction allocation scheme for the control unit should be formulated by weighing economic benefits and environmental impacts produced by each watershed control unit, so as to realize the coordinated development of economy, society and ecological environment in various regions. An efficient and feasible scheme for allocating watershed pollution load reduction is proposed, which serves the implementation of a major national strategy for ecological and environmental protection on land and sea.

### Embodiment I

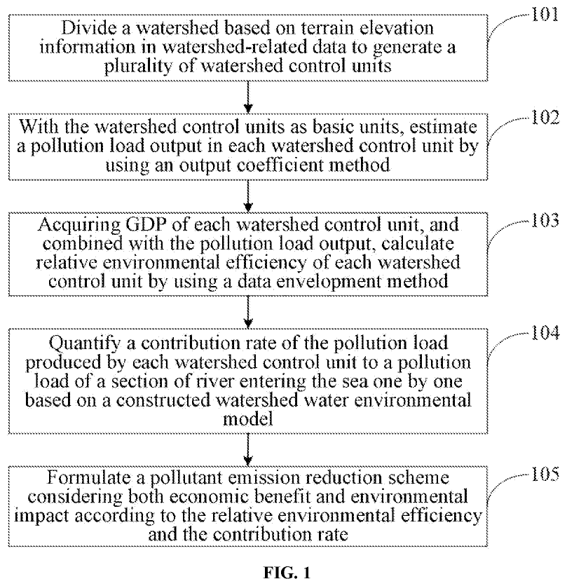

As shown in FIG. 1, a method for allocating total emission reduction of a water environmental pollution load includes steps 101-105.

In step 101, a watershed is divided based on terrain elevation information in watershed-related data to generate multiple watershed control units. The watershed-related data includes meteorology, topographic elevation information, land use information, river water quality, runoff, industrial pollution emission, sewage treatment plant emission, population, livestock and poultry breeding, agricultural planting and county GDP of the watershed.

In practical application, based on the terrain elevation information, the watershed control units are divided by ArcGIS hydrological tools.

In step 102, with the watershed control unit as a basic unit, a pollution load output in each watershed control unit is estimated by using an output coefficient method. The pollution load output includes pollution loads produced by an industrial point source, a sewage treatment plant, agricultural planting, livestock and poultry breeding, and rural life.

In practical application, the pollution load output is:

$$L = {\sum }_{i = 1}^{n} {E}_{i} {A}_{i} ;$$

where L is the pollution load output; i is a pollution source type which includes an industrial point source, a sewage treatment plant, agricultural planting, livestock and poultry breeding and rural life; n is the total number of pollution source types; Eᵢ is a source intensity coefficient of each pollution source, which is acquired by field investigation, and refers to National Technical guidelines of water environmental capacity and related industry standards; Aᵢ is industrial sewage discharge of an i-th pollution source type, water discharge of the sewage treatment plant, agricultural planting area, livestock and poultry breeding quantity, and rural population.

In step 103, GDP (Gross Domestic Product) of each watershed control unit is acquired, and combined with the pollution load output, relative environmental efficiency of each watershed control unit is calculated by using a data envelopment method. The relative environmental efficiency is an economic benefit brought by the pollution output of each watershed control unit.

In practical application, based on the GDP of each watershed control unit and the pollution load output of each watershed control unit obtained in step 102, the relative environmental efficiency of each watershed control unit, i.e., the economic benefit brought by the pollution output, is calculated by using a Data Envelopment Analysis (DEA) method.

The flow of the DEA method is as follows.

Selection of a decision-making unit, where the watershed control unit is taken as the decision-making unit;

Determination of input data of the model, where the pollution load of each watershed control unit is taken as an input and the GDP is taken as an output, both of which are input data of a DEA model; and

Determination of output result of the DEA model: the calculation result is the relative environmental efficiency of each watershed control unit, and the larger the value, the higher the economic benefit brought by the unit pollution output of the control unit. The relative environmental efficiency of the control unit k is obtained by the following method:

$$Objective : min {θ}_{k}$$

$$Constraints : {\sum }_{j = 1}^{n} {x}_{j} {λ}_{j} \leq {x}_{k} {θ}_{k} \qquad ( 1 )$$

$${\sum }_{j = 1}^{n} {y}_{j} {λ}_{j} \geq {y}_{k} \qquad ( 2 )$$

$${\sum }_{j = 1}^{n} {λ}_{j} = 1 \qquad ( 3 )$$

where min θₖ is the relative environmental efficiency of a control unit k, which is the minimum value of θₖ satisfying the constraints (1), (2), (3); Xₖ is a pollution load input of the control unit k, xⱼ is a pollution load input of a control unit j, λⱼ is a weight coefficient of the control unit j (obtained by the constraints of formulas (2) and (3)), the value of j is 1, 2, 3 . . . , n, n is a total number of watershed control units, yⱼ is a GDP output of the control unit j, and yₖ is a GDP output of the control unit k.

In step 104, a contribution rate of the pollution load produced by each watershed control unit to a pollution load of a section of river entering the sea is quantified one by one based on a constructed watershed water environmental model. The contribution rate is the influence of the pollution load produced by each watershed control unit on a water environment of the section of river entering the sea.

In practical application, before the step 104, the method further includes: simulating runoff data of a river channel section, and calculating a Nash-Sutcliffe coefficient between the simulated runoff data and measured runoff data of the river channel section to calibrate hydrological parameters; on the basis of the calibration of the hydrological parameters, calibrating water quality parameter according to water quality concentration data of the river channel section, and determining model parameters of a watershed water environmental model; and constructing the watershed water environmental model according to the model parameters.

In practical application, a watershed water environmental model is constructed based on a SWAT (Soil and Water Assessment Tool) model platform. The input data of the model are data of DEM (Digital Elevation Model), land use, spatial information of soil type, meteorology (precipitation, air temperature, relative humidity, wind speed, sunshine duration), and pollution load of each pollution source in each watershed control unit.

The hydrological parameters are calibrated and verified based on the runoff data of the river channel section. When the Nash-Sutcliffe model efficiency coefficient (NSE) between the simulated runoff and the measured runoff is greater than 0.7, the hydrological parameters are calibrated. Then, based on the water quality concentration data of the river channel section, the water quality parameters are calibrated. When the correlation between the simulated water quality concentration and the measured water quality concentration reaches NSE>0.5, the model parameters can be determined and the model construction can be completed.

In practical application, quantifying environmental impact of a pollution output of the control unit specifically includes the following steps.

Based on the constructed water environmental model, contribution rates of pollution outputs of different control units to the total pollution load of the section of river entering the sea are quantified one by one.

Specifically, in a case that the pollution loads of all watershed control units are taken as the model input, a simulated pollution load value of the section of river entering the sea is taken as a reference. By removing the pollution load input of one watershed control unit and running the model, a pollution load value of the section of river entering the sea is obtained, and a contribution of the watershed control unit to the total load of the section of river entering the sea is obtained by making a difference between the obtained pollution load value and the reference. In a similar way, by removing the pollution loads of the watershed control units one by one, a contribution of a pollution load produced by each watershed control unit to the total pollution load of the section of river entering the sea is quantified. A ratio of the load contribution of each control unit to the total load of the section of river entering the sea is the contribution rate of each control unit to the pollution load of the section of river entering the sea, i.e., the impact on the water environment of the section of river entering the sea.

In practical application, what the water environmental model simulates is the actual situation: the real pollution load (where all control units are polluted) is input into the water environmental model to obtain a simulated pollution load of the section of river entering the sea [for example, 100]. To quantify the contribution of each watershed control unit to the total load output, this watershed control unit is removed at the time of input, and the remaining watershed control units are input into the water environmental model to obtain a load of the section of river entering the sea [for example, 90], which means that with this watershed control unit, the output is 100, and without this watershed control unit, the output is 90. Therefore, the contribution of this watershed control unit is 10, and its contribution rate is 10/100=0.1.

In step 105, the pollutant emission reduction scheme considering both economic benefit and environmental impact is formulated according to the relative environmental efficiency and the contribution rate. The pollutant emission reduction scheme is used for allocating total emission reduction of the water environmental pollution load to each watershed control unit.

In practical application, combined with the economic benefit of each watershed control unit and the influence of each watershed control unit on the water quality of the section of river entering the sea, the specified total pollutant emission reduction is allocated to each watershed control unit. The specific allocation method is as follows. The normalized economic benefit of each watershed control unit is taken as a weight, the weight is multiplied by the contribution rate of each watershed control unit to the water quality pollution, and then the multiplication result is normalized to obtain a final emission reduction allocation proportion of each watershed control unit. The pollution load of each watershed control unit after emission reduction is re-input into the model to verify whether the water quality of the section of river entering the sea meets the standard, so as to formulate a pollution reduction scheme that weighs the economic benefits and environmental impacts to ensure the economic benefit of the watershed control units to the maximum extent when the water quality of the section of river entering the sea meets the standard.

Aiming at the rivers entering the sea with water quality exceeding the standard, the control units of the watershed are taken as the basic emission reduction units, and the economic benefit outputs of the control units related to point and non-point source pollution emission are qualified by using the data envelopment analysis model. Meanwhile, based on the water quality model, the contribution rate of pollution output of each watershed control unit to the total pollution load of the section of river entering the sea is quantified, and a pollution emission reduction scheme for each watershed control unit is ultimately formulated by coordinating the economic benefit and the environmental impact.

The pollution emission reduction is carried out for each river watershed control unit, and the economic benefit brought by local pollution output is considered during emission reduction, that is, relatively less emission reduction can be carried out for those with high economic benefit, and relatively more emission reduction can be carried out for those with low economic benefit but great environmental impact. This method not only ensures that the water quality of the section of river entering the sea reaches the standard to improve the water environment of rivers and estuaries, but also supports the sustainable development of regional economy. The method is clear in principle, systematic and easy to operate and understand, which can provide technical support for the formulation of watershed pollution reduction schemes and serve the treatment and management of water environment.

### Embodiment II

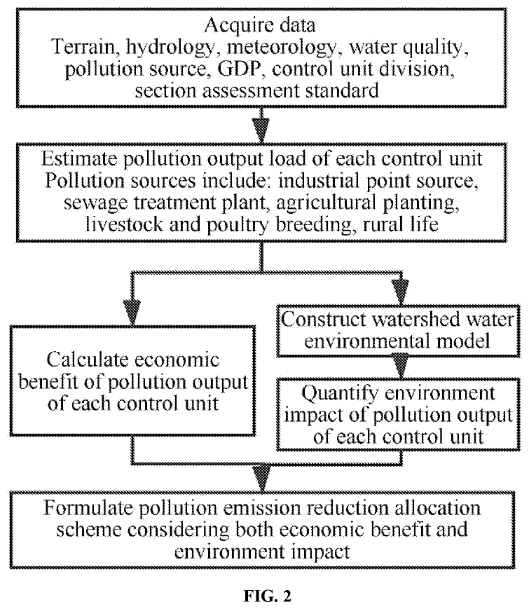

A main stream of Liaohe River watershed is selected as a study region, and the total emission reduction of ammonia nitrogen pollutants is taken as an example. As shown in FIG. 2, the economic benefit brought by the pollutant output is calculated by a DEA method. Meanwhile, an ammonia nitrogen water quality model is constructed to quantify the environmental impact of an ammonia nitrogen pollution output of each watershed control unit on ammonia nitrogen load at the section of river entering the sea, i.e., a contribution rate. Finally, for each watershed control unit, a pollution emission reduction allocation scheme considering both the economic benefit and the environmental impact is formulated.

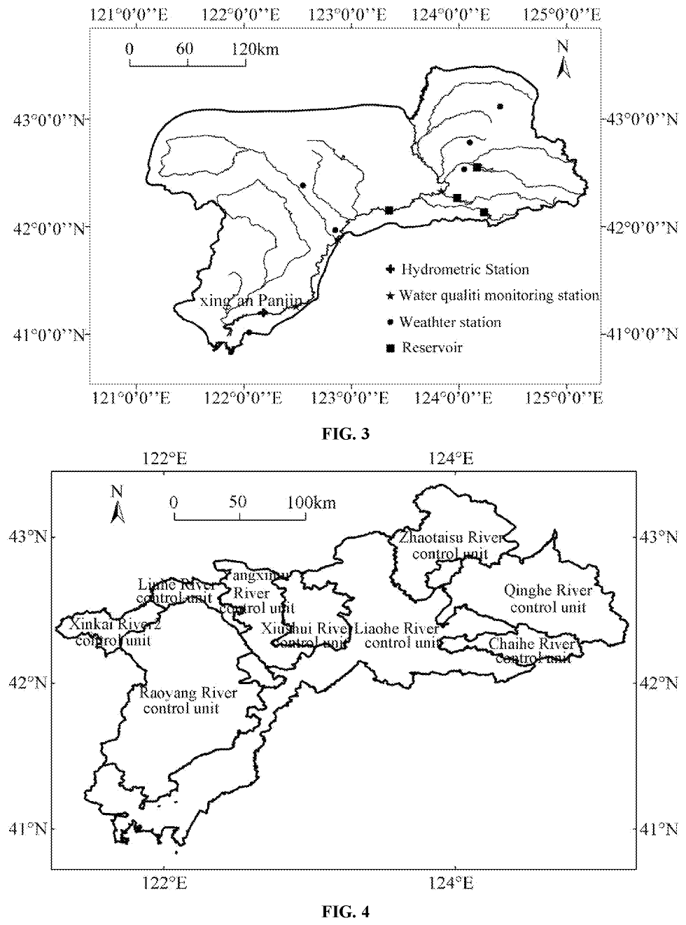

(1) Acquisition of data: DEM elevation data of a main stream watershed of Liaohe River is acquired, with a spatial resolution of 90 m×90 m. The grid data of land use and soil type in the main stream watershed of Liaohe River are acquired, with a spatial resolution of 1 km×1 km. Meteorological data of seven meteorological stations and hydrological data of three hydrological stations (Tieling Station, Ping'anbao Station and Liujianfang Station) in the main stream watershed of Liaohe River from 1999 to 2019 and water quality data of the section of river entering the sea at Xing'an, Panjin from 2015 to 2019 are collected. The spatial distribution of various stations is shown in FIG. 3. Watershed control units divided in the main stream of Liaohe River are collected, as shown in FIG. 4. Pollution emission data and GDP data of counties and districts are collected.

(2) Estimation of pollution load: The control units are used as basic units, an output coefficient method is used to estimate ammonia nitrogen outputs of main pollution sources in the watershed, including an industrial point source, a sewage treatment plant, agricultural planting, livestock and poultry breeding and rural life, and the total ammonia nitrogen outputs of various watershed control units are obtained by addition. The results are shown in FIG. 5.

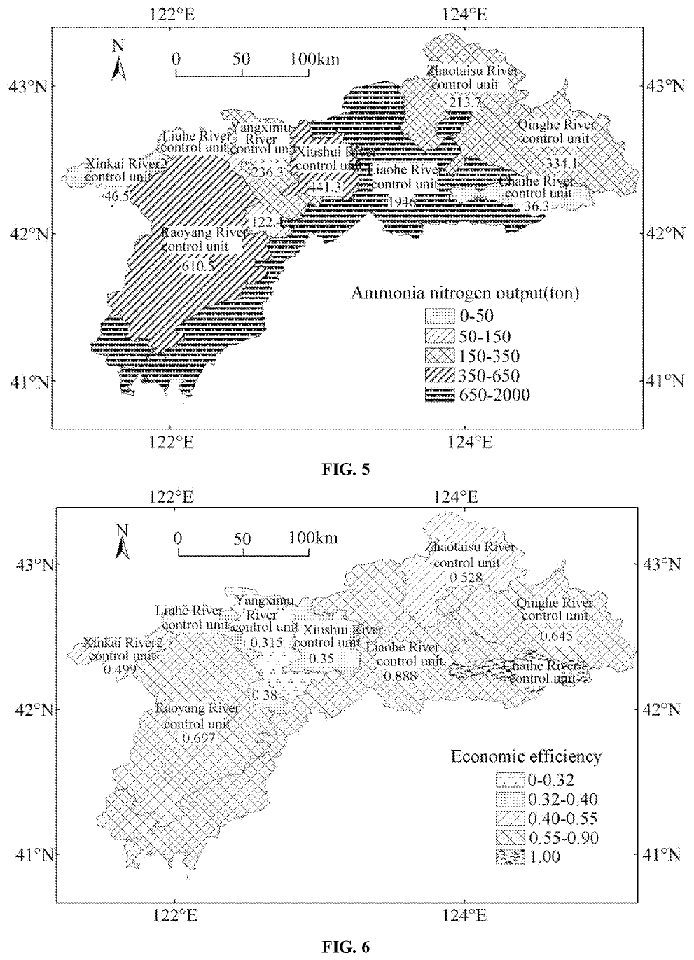

(3) Calculation of economic benefit of pollution output based on DEA method: based on GDP of each watershed control unit, and combined with the ammonia nitrogen output of each control unit obtained in the step (2), economic benefit of each watershed control unit is calculated by a DEA method. Firstly, the control unit is selected as a decision-making unit in the DEA method. Secondly, an index system is established, which takes ammonia nitrogen of each watershed control unit as an input and the GDP as an output. Then, DEAP2.1 software is selected for calculation. Finally, a calculation result is the economic benefit of each watershed control unit. The larger the value, the higher the economic benefit brought by the unit pollution output of the control unit, as shown in FIG. 6.

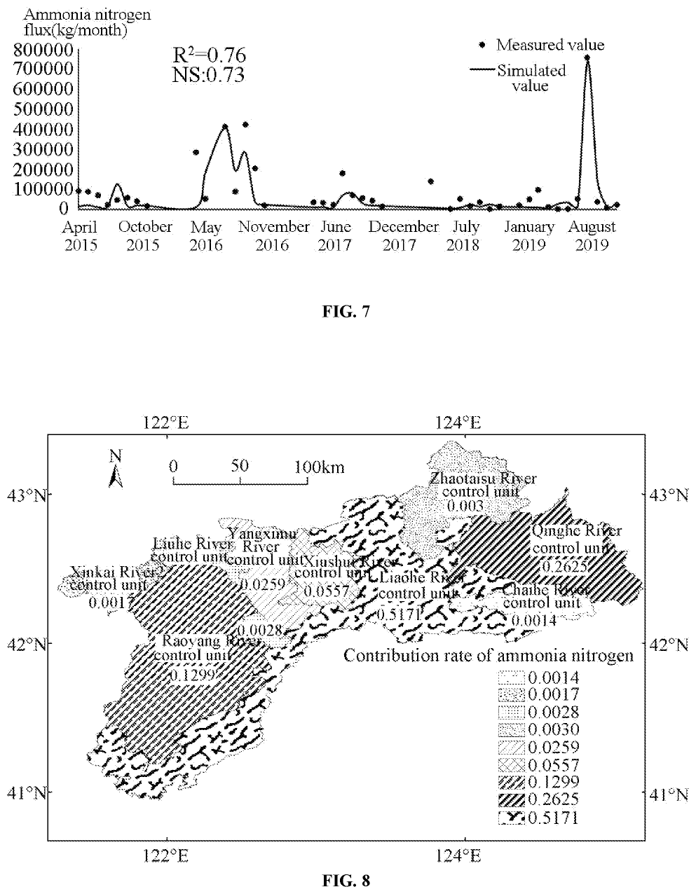

(4) Construction of watershed water environmental model: based on spatial information such as topography, land use and soil type, and combined with hydrological, meteorological and pollution emission data, a SWAT water environmental model is constructed, and the model is calibrated based on monitored runoff and water quality data. The calibration results of the water quality model are shown in FIG. 7, and the overall simulation results meet the accuracy requirements.

(5) Analysis of environmental impact of pollution output of each watershed control unit on water quality of section of river entering the sea: based on the model calibrated in the step (4), the migration and transformation law of pollutants is simulated, and the difference of pollution load of the section of downstream river entering the sea is simulated as the contribution of the control unit by setting and then without setting the pollution load input of each watershed control unit one by one. In a similar way, the contribution rate of each control unit to the water quality pollution of the section of river entering the sea, i.e., the environmental impact, is quantified, and the results are shown in FIG. 8.

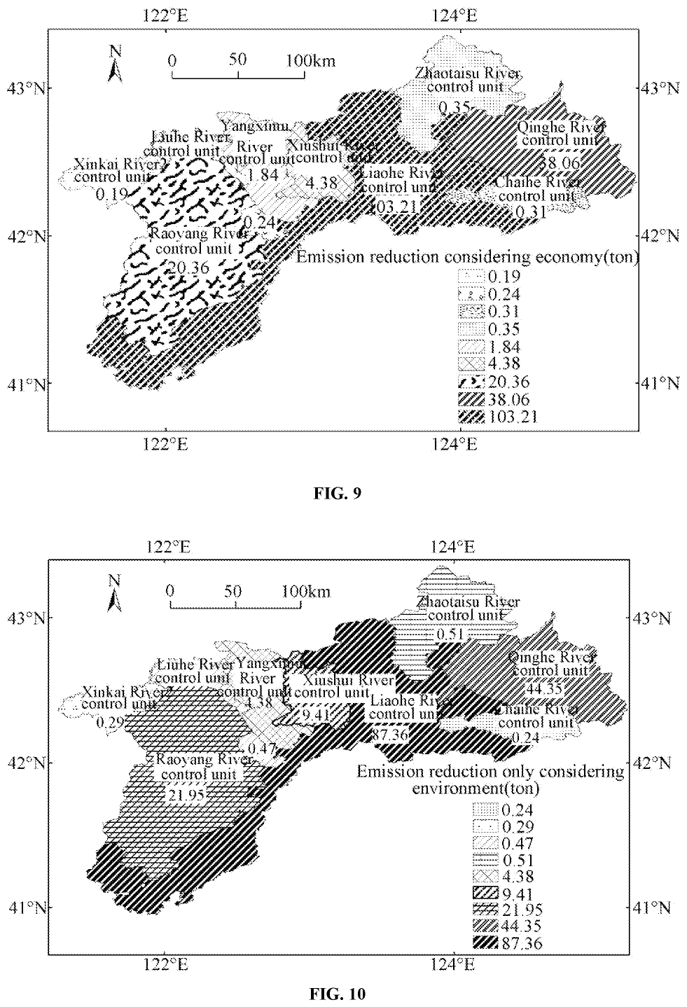

(6) Formulation of a pollutant emission reduction scheme considering both economic benefit and environmental impact: the normalized economic benefit of each watershed control unit is taken as a weight, the weight is multiplied by the contribution rate of each watershed control unit to the water quality pollution, and then the multiplication result is normalized to obtain a final emission reduction allocation proportion of each watershed control unit. According to the reduction of 25% of the average load entering the sea for many years, the total emission reduction of ammonia nitrogen is determined to be 168 t/year, the total emission reduction is allocated in proportion, and the pollution load of each watershed control unit after emission reduction is re-input into the model for simulation to obtain that the ammonia nitrogen concentration in Xing'an section of Panjin changed from 0.18 mg/L to 0.88 mg/L from April to November 2016, which has reached the Class IV water quality standard. Therefore, the spatial emission reduction scheme considering both economic benefit and environmental impact is obtained. The allocation of the emission reduction scheme obtained by this method is compared with the allocation of the emission reduction scheme only considering the environmental impact to obtain results as shown in FIG. 9 to FIG. 10.

By comparison, it is found that the emission reductions allocated to different control units by the two methods are different when the total emission reduction is constant. This method can reflect the economic benefit brought by unit pollution output, and take the economic benefit as a weight to optimize a spatial emission reduction proportion of each watershed control unit. For example, relatively less emission reduction can be carried out for the control unit with high economic benefit under the same environmental impact, and on the contrary, relatively more emission reduction can be carried out for the control unit with low economic benefit, which can greatly reduce the negative impact of pollution emission reduction on regional economy, and ensure that the water quality of the control section entering the sea can reach the standard.

### Embodiment III

In order to implement a method corresponding to Embodiment I and achieve corresponding functions and technical effects, a system for allocating total emission reduction of a water environmental pollution load is provided below.

The system for allocating total emission reduction of a water environmental pollution load includes:
a division module, configured to divide a watershed based on terrain elevation information in watershed-related data to generate multiple watershed control units, where the watershed-related data includes meteorology, topographic elevation information, land use information, river water quality, runoff, industrial pollution emission, sewage treatment plant emission, population, livestock and poultry breeding, agricultural planting and county GDP of the watershed;
an estimation module, configured to estimate a pollution load output in each watershed control unit with the watershed control units as a basic unit and by using an output coefficient method, where the pollution load output includes pollution loads produced by an industrial point source, a sewage treatment plant, agricultural planting, livestock and poultry breeding, and rural life;
a relative environmental efficiency calculation module, configured to acquire GDP (Gross Domestic Product) of each watershed control unit, and combined with the pollution load output, to calculate relative environmental efficiency of each watershed control unit by using a data envelopment method, where the relative environmental efficiency is an economic benefit brought by the pollution output of each watershed control unit;
a contribution rate calculation module, configured to quantify a contribution rate of the pollution load produced by each watershed control unit to a pollution load of a section of river entering the sea one by one based on a constructed watershed water environmental model, where the contribution rate is the influence of the pollution load produced by each watershed control unit on a water environment of the section of river entering the sea; and
a pollutant emission reduction scheme formulating module, configured to formulate a pollutant emission reduction scheme considering both economic benefit and environmental impact according to the relative environmental efficiency and the contribution rate, where the pollutant emission reduction scheme is used for allocating total emission reduction of the water environmental pollution load for each watershed control unit.

### Embodiment IV

An electronic device includes a memory and a processor. The memory is used to store a computer program, and the processor is used to run the computer program to enable the electronic device to implement the method for allocating total emission reduction of the water environmental pollution load of Embodiment I.

A computer-readable storage medium stores a computer program. The computer program, when executed by a processor, implements the method for allocating total emission reduction of the water environmental pollution load of Embodiment I.

Embodiments in this specification are described in a progressive manner, each embodiment focuses on differences from other embodiments, and the same and similar parts between the embodiments may refer to each other. Since the system disclosed in the embodiments corresponds to the method disclosed in the embodiments, the description thereof is relatively simple, and reference may be made to the method description.

Several examples are used for illustration of the principles and implementations of the present disclosure. The description of the embodiments is merely used to help illustrate the method and its core ideas of the present disclosure. In addition, those of ordinary skill in the art can make various modifications in terms of specific embodiments and the scope of application in accordance with the teachings of the present disclosure. In conclusion, the content of this specification shall not be construed as a limitation to the present disclosure.

1. A method for allocating total emission reduction of a water environmental pollution load, comprising:
dividing a watershed based on terrain elevation information in watershed-related data to generate a plurality of watershed control units, wherein the watershed-related data comprises meteorology, topographic elevation information, land use information, river water quality, runoff, industrial pollution emission, sewage treatment plant emission, population, livestock and poultry breeding, agricultural planting and county GDP of the watershed;
with a watershed control unit as a basic unit, estimating a pollution load output in each watershed control unit by using an output coefficient method, wherein the pollution load output comprises pollution loads produced by an industrial point source, a sewage treatment plant, agricultural planting, livestock and poultry breeding, and rural life;
acquiring GDP (Gross Domestic Product) of each watershed control unit, and combined with the pollution load output, calculating relative environmental efficiency of each watershed control unit by using a data envelopment method, wherein the relative environmental efficiency is an economic benefit brought by the pollution output of each watershed control unit;
quantifying a contribution rate of a pollution load produced by each watershed control unit to a pollution load of a section of river entering the sea one by one based on a constructed watershed water environmental model, wherein the contribution rate is influence of the pollution load produced by each watershed control unit on a water environment of the section of river entering the sea; and
formulating a pollutant emission reduction scheme considering both an economic benefit and an environmental impact according to the relative environmental efficiency and the contribution rate, wherein the pollutant emission reduction scheme is configured to allocate total emission reduction of the water environmental pollution load for each watershed control unit.

2. The method according to claim 1, wherein the pollution load output is:
$$L = {\sum }_{i = 1}^{n} {E}_{i} {A}_{i} ;$$
wherein L is a pollution load output; i is a pollution source type, the pollution source type comprises the industrial point source, the sewage treatment plant, the agricultural planting, the livestock and poultry breeding and the rural life; n is a total number of pollution source types; Eᵢ is a source intensity coefficient of each pollution source; Aᵢ is industrial sewage discharge of a i-th pollution source type, water discharge of the sewage treatment plant, agricultural planting area, livestock and poultry breeding quantity, and rural population.

3. The method according to claim 1, wherein before quantifying the contribution rate of a pollution load produced by each watershed control unit to the pollution load of the section of river entering the sea one by one based on the constructed watershed water environmental model, the method further comprises:
simulating runoff data of a river channel section, and calculating a Nash-Sutcliffe coefficient between the simulated runoff data of the river channel section and measured runoff data of the river channel to calibrate a hydrological parameter;
on the basis of completing the calibration of the hydrological parameter, calibrating a water quality parameter according to water quality concentration data of the river channel section, and determining a model parameter of a watershed water environmental model; and
constructing the watershed water environmental model according to the model parameter.

4. The method according to claim 1, wherein quantifying the contribution rate of the pollution load produced by each watershed control unit to the pollution load of the section of river entering the sea one by one based on the constructed watershed water environmental model comprises:
with pollution loads produced by all the watershed control units as an input of the watershed water environmental model, simulating a pollution load value of the section of river entering the sea;
with the simulated pollution load value as a reference, removing one of the watershed control units, and running the watershed water environmental model to determine a current pollution load value of the section of river entering the sea;
determining a contribution of a pollution load produced by the removed watershed control unit to the pollution load of the section of river entering the sea according to a difference between the current pollution load value and the simulated pollution load value;
removing one of the watershed control units one by one, and quantifying a contribution of a pollution load produced by each watershed control unit to the pollution load of the section of river entering the sea; and
calculating a ratio of the contribution of the pollution load produced by each watershed control unit to the pollution load of the section of river entering the sea and a total load of the section of river entering the sea, and determining the contribution rate of the pollution load produced by each watershed control unit to the pollution load of the section of river entering the sea.

5. The method according to claim 1, wherein formulating the pollutant emission reduction scheme considering both the economic benefit and the environmental impact according to the relative environmental efficiency and the contribution rate comprises:
normalizing the relative environmental efficiency of each watershed control unit, and assuming the normalized relative environmental efficiency as a relative environmental efficiency weight;
multiplying the relative environmental efficiency weight with the contribution rate of each watershed control unit to obtain a multiplication result;
normalizing the multiplication result to determine an emission reduction allocation proportion of each watershed control unit; and
performing emission reduction for each watershed control unit according to the emission reduction allocation proportion, and inputting the pollution load of each watershed control unit after emission reduction to the watershed water environmental model to verify whether the water quality of the section of river entering the sea reaches a standard, and formulating the pollutant emission reduction scheme.

6. A system for allocating total emission reduction of a water environmental pollution load, comprising:
a division module, configured to divide a watershed based on terrain elevation information in watershed-related data to generate a plurality of watershed control units, wherein the watershed-related data comprises meteorology, topographic elevation information, land use information, river water quality, runoff, industrial pollution emission, sewage treatment plant emission, population, livestock and poultry breeding, agricultural planting and county GDP of the watershed;
an estimation module, configured to estimate a pollution load output in each watershed control unit with a watershed control unit as a basic unit and by using an output coefficient method, wherein the pollution load output comprises pollution loads produced by an industrial point source, a sewage treatment plant, agricultural planting, livestock and poultry breeding, and rural life;
a relative environmental efficiency calculation module, configured to acquire GDP (Gross Domestic Product) of each watershed control unit, and combined with the pollution load output, to calculate relative environmental efficiency of each watershed control unit by using a data envelopment method, wherein the relative environmental efficiency is an economic benefit brought by the pollution output of each watershed control unit;
a contribution rate calculation module, configured to quantify a contribution rate of a pollution load produced by each watershed control unit to a pollution load of a section of river entering the sea one by one based on a constructed watershed water environmental model, wherein the contribution rate is influence of the pollution load produced by each watershed control unit on a water environment of the section of river entering the sea; and
a pollutant emission reduction scheme formulating module, configured to formulate a pollutant emission reduction scheme considering both an economic benefit and an environmental impact according to the relative environmental efficiency and the contribution rate, wherein the pollutant emission reduction scheme is configured to allocate total emission reduction of the water environmental pollution load for each watershed control unit.

7. The system according to claim 6, wherein the pollution load output is:
$$L = {\sum }_{i = 1}^{n} {E}_{i} {A}_{i} ;$$
wherein L is the pollution load output; i is a pollution source type, the pollution source type comprises the industrial point source, the sewage treatment plant, the agricultural planting, the livestock and poultry breeding and the rural life; n is a total number of pollution source types; Eᵢ is a source intensity coefficient of each pollution source; Aᵢ is industrial sewage discharge of an i-th pollution source type, water discharge of the sewage treatment plant, agricultural planting area, livestock and poultry breeding quantity, and rural population.

8. The system according to claim 6, further comprising:
a hydrological parameter calibration module, configured to simulate runoff data of a river channel section, and calculate a Nash-Sutcliffe coefficient between the simulated runoff data of the riverchannel section and measured runoff data of the river channel to calibrate a hydrological parameter;
a model parameter determination module, configured to calibrate a water quality parameter according to water quality concentration data of the river channel section on the basis of completing the calibration of the hydrological parameter, and determine a model parameter of a watershed water environmental model; and
a watershed water environmental model construction module, configured to construct the watershed water environmental model according to the model parameter.

9. An electronic device, comprising a memory and a processor, wherein the memory is configured to store a computer program, and the processor is configured to run the computer program to enable the electronic device to implement the method for allocating total emission reduction of the water environmental pollution load according to claim 1.

10. A computer-readable storage medium with a computer program stored thereon, wherein the computer program, when executed by the processor, implements the method for allocating total emission reduction of the water environmental pollution load according to claim 1.
